(19) United States
(12) Patent Application Publication
(10) Pub. No.: US 2024/0333138 A1
(43) Pub. Date: Oct. 3, 2024

(54) CAPACITOR TEMPERATURE ESTIMATION DEVICE AND CAPACITOR TEMPERATURE ESTIMATION METHOD

(71) Applicant: HONDA MOTOR CO., LTD., Tokyo (JP)

(72) Inventor: Eisuke MATSUDA, Saitama (JP)

(21) Appl. No.: 18/586,551

(22) Filed: Feb. 26, 2024

(30) Foreign Application Priority Data
Mar. 31, 2023 (JP) 2023-057987

(51) Int. Cl. H02M 1/32; G01K 7/42; H02M 3/158

(52) U.S. Cl. CPC H02M 1/327; G01K 7/425; H02M 3/158

(57) ABSTRACT

An object is to allow for accurate estimation of a temperature of a capacitor. A capacitor temperature estimation device includes a first obtainer, a first identifier, a second obtainer, a second identifier, and a temperature estimator. The first obtainer obtains own-operating information about an operating state of a boost converter. The first identifier identifies own ripple information, based on the own-operating information obtained and a first table. The second obtainer obtains external operating information about an operating state of external equipment connected to the boost converter. The second identifier identifies external ripple information, based on the external operating information obtained and a second table. The temperature estimator estimates the temperature of the capacitor, based on the own ripple information identified and the external ripple information identified.

This application is based on and claims the benefit of priority from Japanese Patent Application No. 2023-057987, filed on 31 Mar. 2023, the content of which is incorporated herein by reference.

### BACKGROUND OF THE INVENTION

### Field of the Invention

The present invention relates to a capacitor temperature estimation device that estimates the temperature of a capacitor in a boost converter.

### Related Art

Most boost converters smooth power boosted by a reactor or the like, using a capacitor, and output the power.
Patent Document 1: Japanese Unexamined Patent Application, Publication No. 2022-149905

### SUMMARY OF THE INVENTION

The temperature of the capacitor in such a boost converter is increased by ripple current flowing into the capacitor. The temperature of the capacitor can affect the load applied to the capacitor, and the durability and the like of the capacitor. It is thus important to monitor the temperature of the capacitor. Accordingly, the present inventors have conceived of estimating the temperature of the capacitor based on the ripple current flowing into the capacitor.

The present inventors have focused on the fact that in this case, the following problems can occur, though. For example, when predetermined external equipment, such as an inverter, is electrically connected to the output side of a boost converter, not only does own ripple caused by operation of the boost converter flow into the capacitor, but also external ripple caused by operation of the external equipment flows into the capacitor. Accordingly, without consideration of the external ripple, the temperature of the capacitor cannot be accurately estimated. Such a problem can particularly significantly occur when the external equipment is outsourced equipment.

The present invention has been made in view of the circumstances described above, and has an object to allow for accurate estimation of a temperature of a capacitor.

The present inventors have found that identification not only of ripple current flowing into a capacitor due to operation of a boost converter but also of ripple current flowing into the capacitor due to operation of external equipment allows for accurate estimation of a temperature of the capacitor, and have achieved the present invention. The present invention encompasses the following devices (1) to (6), and method (7).

(1) A capacitor temperature estimation device estimating a temperature of a capacitor in a boost converter, including: a first storage configured to store a first table that tabulates a relationship between own-operating information as information about an operating state of the boost converter, and own ripple information as information about own ripple that is ripple current caused by operation of the boost converter;
a first obtainer configured to obtain the own-operating information;
a first identifier configured to identify the own ripple information, based on the own-operating information obtained and the first table;
a second storage configured to store a second table that tabulates a relationship between external operating information as information about an operating state of external equipment electrically connected to the boost converter, and external ripple information as information about external ripple that is ripple current caused by operation of the external equipment;
a second obtainer configured to obtain the external operating information;
a second identifier configured to identify the external ripple information, based on the external operating information obtained and the second table; and
a temperature estimator configured to estimate the temperature of the capacitor, based on the own ripple information identified and the external ripple information identified.

According to this configuration, the own ripple information is identified based on the own-operating state and the first table, and the external ripple information is identified based on the external operating state and the second table. Based on these own ripple information and external ripple information, the temperature of the capacitor is estimated. Accordingly, in consideration not only of the own ripple due to operation of the boost converter but also of the external ripple due to operation of the external equipment, the temperature of the capacitor can be estimated. Accordingly, the temperature of the capacitor can be accurately estimated.

(2) The capacitor temperature estimation device according to (1), further including a loss calculator configured to calculate a power loss in the capacitor, based on the own ripple information identified, the external ripple information identified, and a parasitic impedance that the capacitor has, wherein the temperature estimator estimates the temperature of the capacitor, based on the power loss calculated.

According to this configuration, the temperature of the capacitor can be estimated by a simple scheme.

(3) The capacitor temperature estimation device according to (1) or (2), wherein the external equipment is an inverter that converts power output from the boost converter, into AC power, and supplies the AC power to a motor, and the external operating information includes at least one selected from a voltage output from the boost converter to the inverter, a current output from the boost converter to the inverter, a frequency of the external ripple, and a rotational speed of the motor.

According to this configuration, based on the external operating information including such parameters and the second table, the external ripple information can be identified.

(4) The capacitor temperature estimation device according to (1) or (2), wherein the own-operating information includes at least one selected from current input into the boost converter, a frequency of the own ripple, and a boost ratio of the boost converter.

According to this configuration, based on the own-operating information including such parameters, and the first table, the own ripple information can be identified.

(5) The capacitor temperature estimation device according to (1) or (2),
wherein the second identifier includes:
a temporary external ripple identifier configured to identify a temporary value of the external ripple, based on the external operating information and the second table;
an external gain identifier configured to identify an external gain as a ratio of a value of the external ripple to the temporary value of the external ripple, based on a frequency of the external ripple; and
an external ripple identifier configured to identify the value of the external ripple that is to flow into the capacitor, based on the temporary value of the external ripple identified and the external gain identified, and
wherein the temperature estimator estimates the temperature of the capacitor, based on the value of the external ripple identified.

It is conceivable that due to the difference in the frequency of the external ripple, the impedance of wiring from the source of the external ripple to the capacitor changes, and the external ripple flowing into the capacitor changes accordingly. In regard to this point, according to this configuration, based on the frequency of the external ripple, the external gain can be identified, and the value of the external ripple flowing into the capacitor can be corrected.

(6) The capacitor temperature estimation device according to (1) or (2),
wherein the first identifier includes:
a temporary own ripple identifier configured to identify a temporary value of the own ripple, based on the own-operating information and the first table;
an own gain identifier configured to identify an own gain as a ratio of a value of the own ripple to the temporary value of the own ripple, based on a frequency of the own ripple; and an own ripple identifier configured to identify the value of the own ripple that is to flow into the capacitor, based on the temporary value of the own ripple identified and the own gain identified, and
wherein the temperature estimator estimates the temperature of the capacitor, based on the value of the own ripple identified.

It is conceivable that due to the difference in the frequency of the own ripple, the impedance of wiring from the source of the own ripple to the capacitor changes, and the own ripple flowing into the capacitor changes accordingly. In regard to this point, according to this configuration, based on the frequency of the own ripple, the own gain can be identified, and the value of the own ripple flowing into the capacitor can be corrected.

(7) A capacitor temperature estimation method estimating a temperature of a capacitor in a boost converter, including: creating a first table that tabulates a relationship between own-operating information as information about an operating state of the boost converter, and own ripple information as information about own ripple that is ripple current caused by operation of the boost converter;
obtaining the own-operating information;
identifying the own ripple information, based on the own-operating information obtained and the first table;
creating a second table that tabulates a relationship between external operating information as information about an operating state of external equipment electrically connected to the boost converter, and external ripple information as information about external ripple that is ripple current caused by operation of the external equipment;
obtaining the external operating information;
identifying the external ripple information, based on the external operating information obtained and the second table; and
estimating the temperature of the capacitor, based on the own ripple information identified and the external ripple information identified.

According to this method, advantageous effects similar to those of the device (1) can be achieved.

As described above, according to the device (1) and the method (7), the temperature of the capacitor can be accurately estimated. Furthermore, according to the devices (2) to (6) citing (1), respective additional advantageous effects can be achieved.

### BRIEF DESCRIPTION OF THE DRAWINGS

FIG. 1 is a configuration diagram illustrating a capacitor temperature estimation device according to a first embodiment;

FIG. 2 is a circuit diagram illustrating a capacitor and its peripheral circuitry;

FIG. 3 schematically illustrates a first table;

FIG. 4 is a graph illustrating temporal change in own ripple;

FIG. 5 is a graph illustrating the relationship between input current, and the own ripple amplitude;

FIG. 6 is a graph illustrating the relationship between the own ripple frequency, and the own gain;

FIG. 7 schematically shows a second table;

FIG. 8 is a graph showing the relationship between external input current and the external ripple amplitude;

FIG. 9 is a graph showing the relationship between the motor rotational speed and the external ripple amplitude;

FIG. 10 is a graph illustrating the relationship between the external ripple frequency and the external gain; and

FIG. 11 is a graph showing the relationship between the frequency of ripple and the parasitic impedance.

### DETAILED DESCRIPTION OF THE INVENTION

Hereinafter, embodiments of the present invention are described with reference to the drawings. Note that the present invention is not necessarily limited to the following embodiments, and can be appropriately changed in a range without departing from the spirit of the present invention.

### First Embodiment

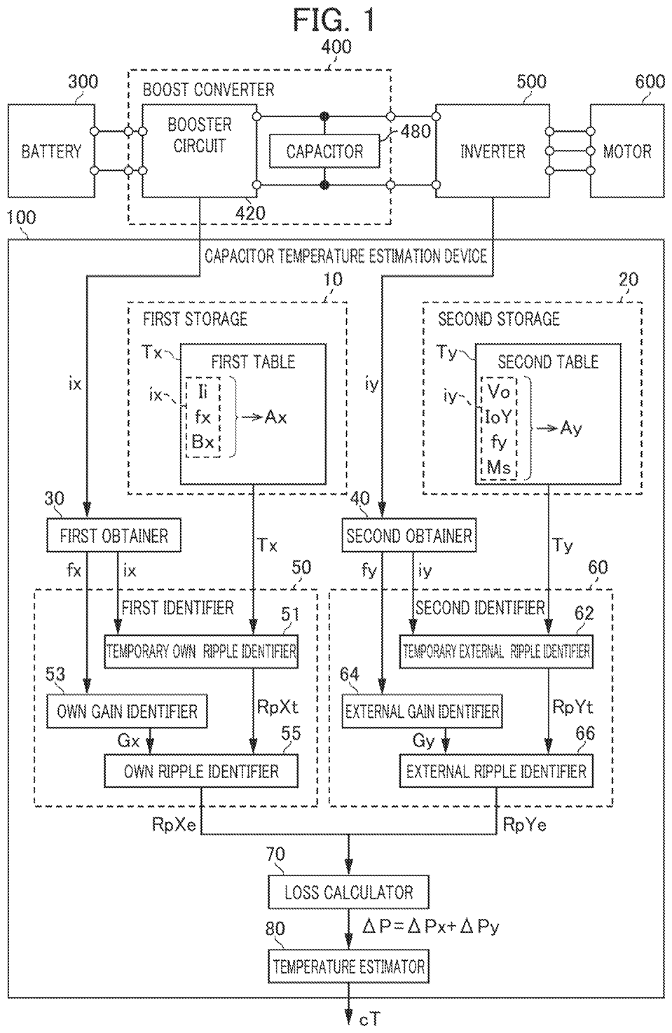

A capacitor temperature estimation device 100 according to this embodiment illustrated in FIG. 1 estimates the temperature of a capacitor 480 provided on an output side of a boost converter 400. The boost converter 400 boosts power supplied from a battery 300, and supplies the power to an inverter 500. The inverter 500 converts the supplied power into AC power, and supplies the power to a motor 600. Note that “inverter 500” may be read as “external equipment”.

The battery 300 may be, for example, a lithium-ion battery or the like.

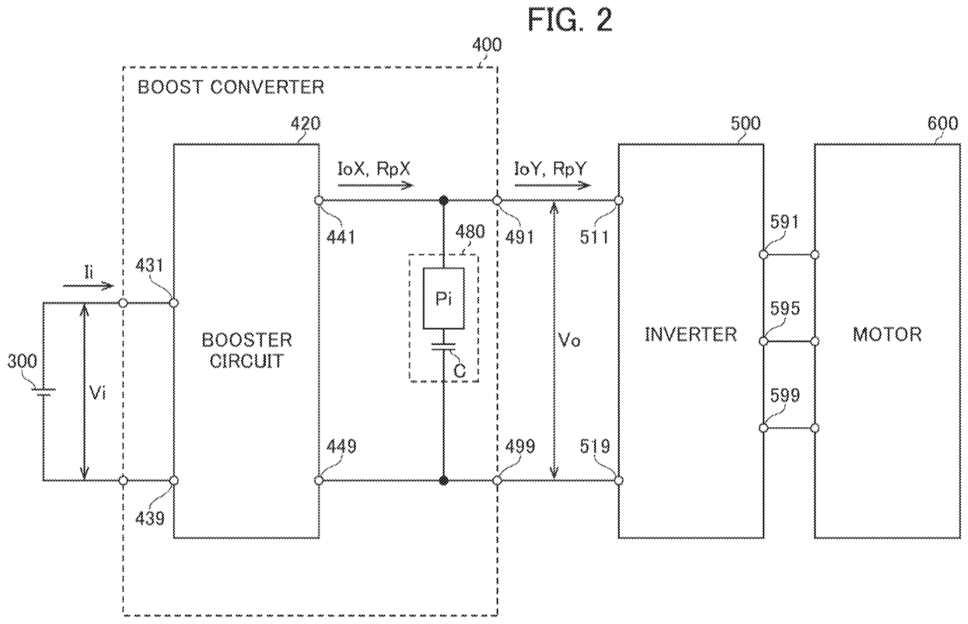

As illustrated in FIG. 2, the boost converter 400 includes a booster circuit 420, and the capacitor 480 for smoothing. According to this embodiment, the booster circuit 420 is a three-phase boost chopper circuit that includes three coils for boost, and is configured to allow executing single-phase drive, two-phase drive, and three-phase drive. Note that the booster circuit 420 may be, for example, a single-phase boost chopper circuit, or a transformer circuit that includes full-bridge circuits on both the input side and the output side that sandwich a reactor.

An input terminal 431 on a positive side of the booster circuit 420 is electrically connected to a positive terminal of the battery 300. An input terminal 439 on a negative side of the booster circuit 420 is electrically connected to a negative terminal of the battery 300. Hereinafter, the voltage between terminals on the input side of the booster circuit 420 is called “input voltage Vi”. The input voltage Vi is substantially identical to the voltage between terminals of the battery 300. Hereinafter, current input into the input terminals 431 and 439 of the booster circuit 420 is called “input current Ii”.

The booster circuit 420 boosts the input voltage Vi supplied from the battery 300 to the input terminals 431 and 439, and outputs the voltage from output terminals 441 and 449. The output terminal 441 on the positive side of the booster circuit 420 is electrically connected to the positive terminal of the capacitor 480, and electrically connected to the output terminal 491 on the positive side of the entire boost converter 400. The output terminal 449 on the negative side of the booster circuit 420 is electrically connected to the negative terminal of the capacitor 480, and electrically connected to the output terminal 499 on the negative side of the entire boost converter 400. Hereinafter, the temperature of the capacitor 480 is called “capacitor temperature cT”.

Hereinafter, current output from the output terminals 441 and 449 of the booster circuit 420 is called “own output current IoX”. The own output current IoX contains “own ripple RpX” that is ripple current due to operation of the booster circuit 420. The own ripple RpX flows into the capacitor 480.

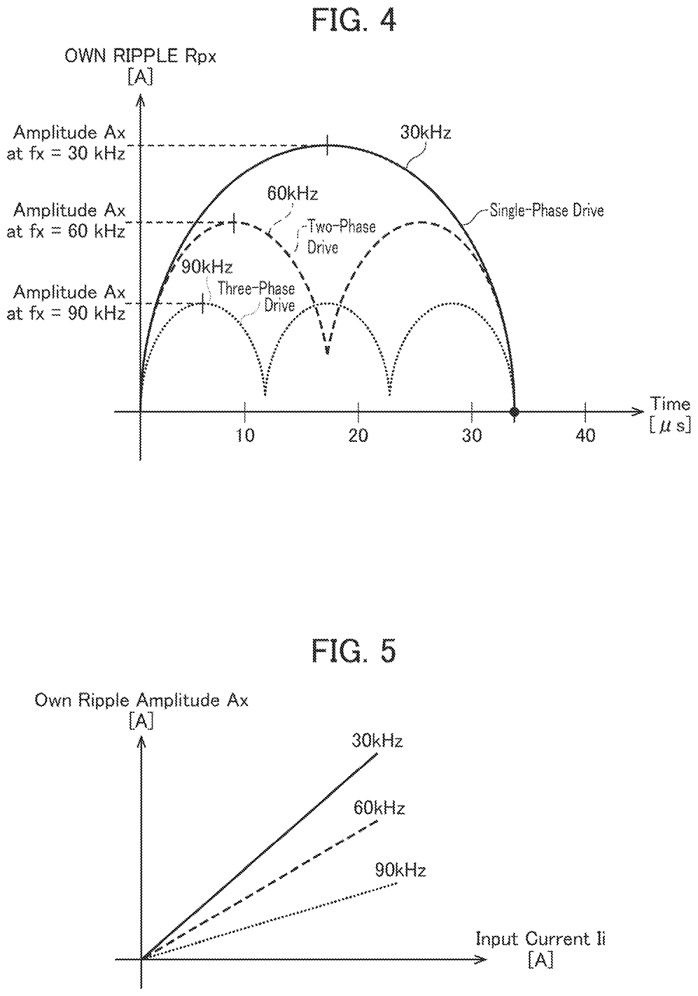

Hereinafter, the frequency of the own ripple RpX is called “own ripple frequency fx”. As illustrated in FIG. 4, the own ripple frequency fx is 30 kHz in a case of single-phase drive, 60 kHz in a case of two-phase drive, and 90 kHz in a case of three-phase drive. Hereinafter, the amplitude of the own ripple RpX is called “own ripple amplitude Ax”.

As illustrated in FIG. 2, the capacitor 480 has a capacitance C as the main functional component, and a parasitic impedance Pi. Hereinafter, the voltage output from the boost converter 400 is called “output voltage Vo”. The output voltage Vo is substantially identical to the voltage between terminals of the capacitor 480. Hereinafter, the subtraction of “100%” from the division of the output voltage Vo by the input voltage Vi is called “boost ratio Bx”.

Input terminals 511 and 519 of the inverter 500 are electrically connected respectively to the output terminals 441 and 449 of the boost converter 400. Thus, the input terminals 511 and 519 of the inverter 500 are electrically connected to the capacitor 480. Hereinafter, current supplied from the boost converter 400 to the inverter 500 is called “external output current IoY”.

The motor 600 for alternating current is electrically connected to output terminals 591, 595, and 599 of the inverter 500. Hereinafter, the rotational speed of the motor 600 is called “motor rotational speed Ms”. The inverter 500 converts power from the boost converter 400 into three-phase AC power, and supplies the power to the motor 600. According to the conversion, the external output current IoY from the boost converter 400 to the inverter 500 contains “external ripple RpY” as ripple current due to operation of the inverter 500. The external ripple RpY flows into the capacitor 480. Hereinafter, the frequency of the external ripple RpY is called “external ripple frequency fy”, and the amplitude of the external ripple RpY is called “external ripple amplitude Ay”.

The capacitor temperature estimation device 100 illustrated in FIG. 1 estimates the temperature of the capacitor 480, based on the own ripple RpX and the external ripple RpY described above. The capacitor temperature estimation device 100 mainly includes a computer provided with a CPU, a ROM, and a RAM. From another viewpoint, the capacitor temperature estimation device 100 includes a first storage 10, a second storage 20, a first obtainer 30, a second obtainer 40, a first identifier 50, a second identifier 60, a loss calculator 70, and a temperature estimator 80.

First, the first storage 10, the first obtainer 30, and the first identifier 50 are described.

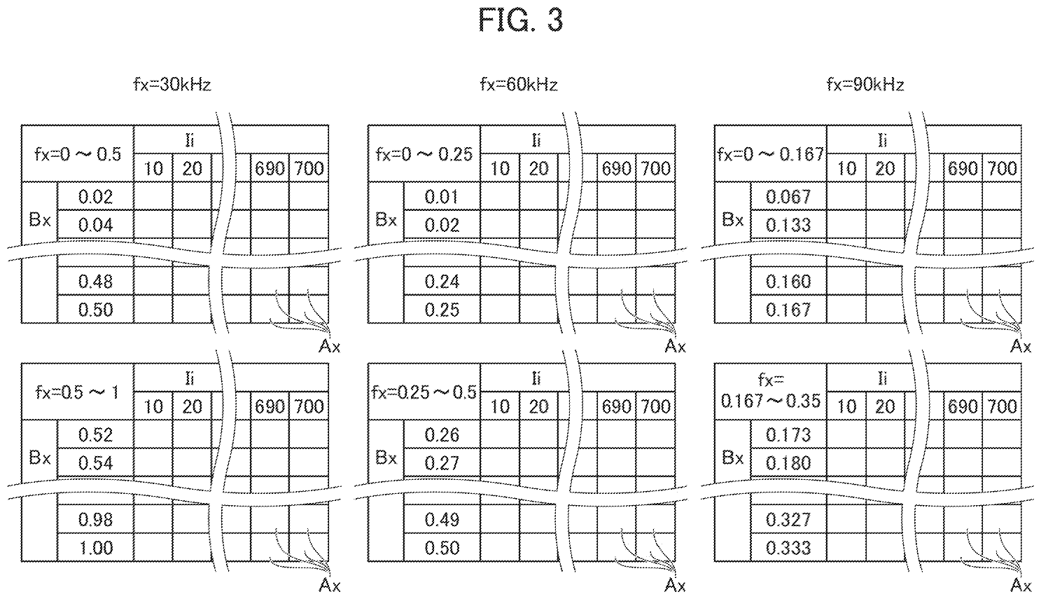

The first storage 10 stores a first table Tx. The first table Tx is a table that tabulates the relationship between own-operating information ix and the own ripple amplitude Ax. Note that “own ripple amplitude Ax” may be read as “own ripple information”. The own-operating information ix is information about the operating state of the boost converter 400. According to this embodiment, the own-operating information ix includes the input current Ii, the own ripple frequency fx, and the boost ratio Bx. Accordingly, as illustrated in FIG. 3, the first table Tx is a three-dimensional table that tabulates the relationship between three-dimensional information on the input current Ii, on the own ripple frequency fx, and on the boost ratio Bx, and the own ripple amplitude Ax.

Specifically, as illustrated in FIG. 4, the smaller the own ripple frequency fx is, the larger the own ripple amplitude Ax is. As illustrated in FIG. 5, if the own ripple frequency fx is the same, the larger the input current Ii is, the larger the own ripple amplitude Ax is. The higher the boost ratio Bx is, the larger the own ripple amplitude Ax is. According to them, the first table Tx is the three-dimensional table as described above. The first table Tx is preliminarily created based on an experiment and a simulation.

The first obtainer 30 illustrated in FIG. 1 obtains the own-operating information ix. That is, the first obtainer 30 obtains the input current Ii, the own ripple frequency fx, and the boost ratio Bx. Specifically, the input current Ii can be obtained by, for example, actual measurement by an ammeter or computation. The own ripple frequency fx can be obtained based on, for example, the frequency of duty control in the boost converter 400. The boost ratio Bx can be obtained by, for example, based on an actually measured value or a computed value of the voltage between terminals of the battery 300, and on an actually measured value or a computed value of the voltage between terminals of the capacitor 480.

The first identifier 50 illustrated in FIG. 1 includes a temporary own ripple identifier 51, an own gain identifier 53, and an own ripple identifier 55. Hereinafter, the effective value of the own ripple RpX is called “own ripple effective value RpXe”, and a temporary value of the own ripple effective value RpXe is called “own ripple temporary effective value RpXt”. Note that “own ripple temporary effective value” may be read as “temporary value of own ripple”, and “own ripple effective value” may be read as “value of own ripple”. Hereinafter, the ratio of the own ripple effective value RpXe to the own ripple temporary effective value RpXt is called “own gain Gx”.

The temporary own ripple identifier 51 illustrated in FIG. 1 identifies the own ripple amplitude Ax, based on the obtained own-operating information ix and the first table Tx. Based on the identified own ripple amplitude Ax, the own ripple temporary effective value RpXt is identified. Specifically, for example, a value obtained by multiplying the own ripple amplitude Ax by a predetermined number is adopted as the own ripple temporary effective value RpXt.

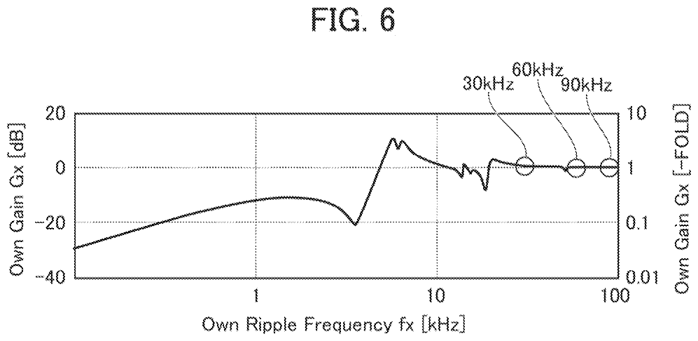

The own gain identifier 53 illustrated in FIG. 1 identifies the own gain Gx, based on the own ripple frequency fx. Specifically, when the own ripple frequency fx changes, the impedance on a path from the source of the own ripple RpX to the capacitor 480 changes. Accordingly, as illustrated in FIG. 6, the own ripple frequency fx, and the own gain Gx have a predetermined relationship. The own gain identifier 53 stores information where such a relationship is stored, and identifies the own gain Gx, based on the own ripple frequency fx and this information.

The own ripple identifier 55 illustrated in FIG. 1 identifies the own ripple effective value RpXe flowing into the capacitor 480, based on the product of the identified own ripple temporary effective value RpXt and the own gain Gx.

Next, the second storage 20, the second obtainer 40, and the second identifier 60 are described.

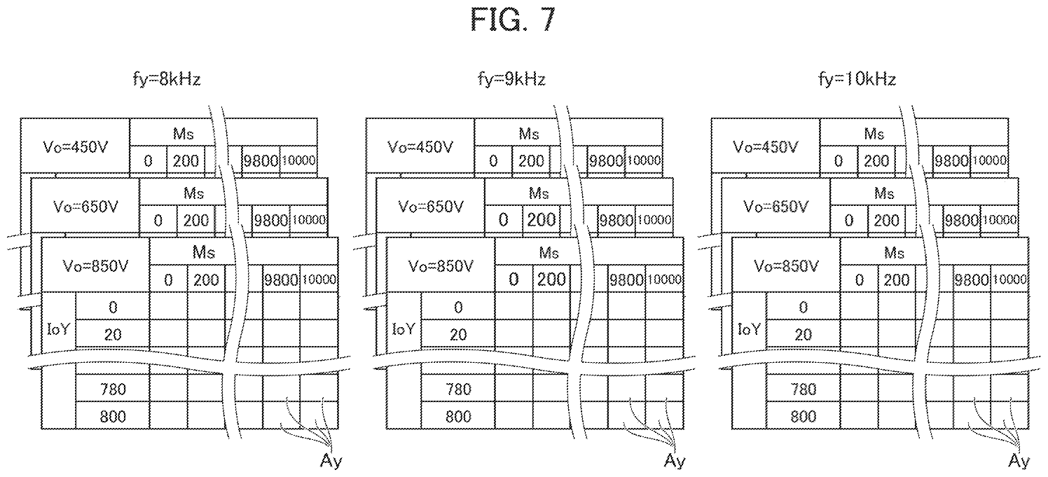

The second storage 20 stores a second table Ty. The second table Ty is a table that tabulates the relationship between external operating information iy and the external ripple amplitude Ay. Note that “external ripple amplitude Ay” may be read as “external ripple information”. The external operating information iy is information about the operating state of the inverter 500. According to this embodiment, the external operating information iy includes the output voltage Vo, the external output current IoY, the external ripple frequency fy, and the motor rotational speed Ms. Accordingly, as illustrated in FIG. 7, the second table Ty is a four-dimensional table that tabulates the relationship between four-dimensional information on the output voltage Vo, on the external output current IoY, on the external ripple frequency fy, and on the motor rotational speed Ms, and the external ripple amplitude Ay.

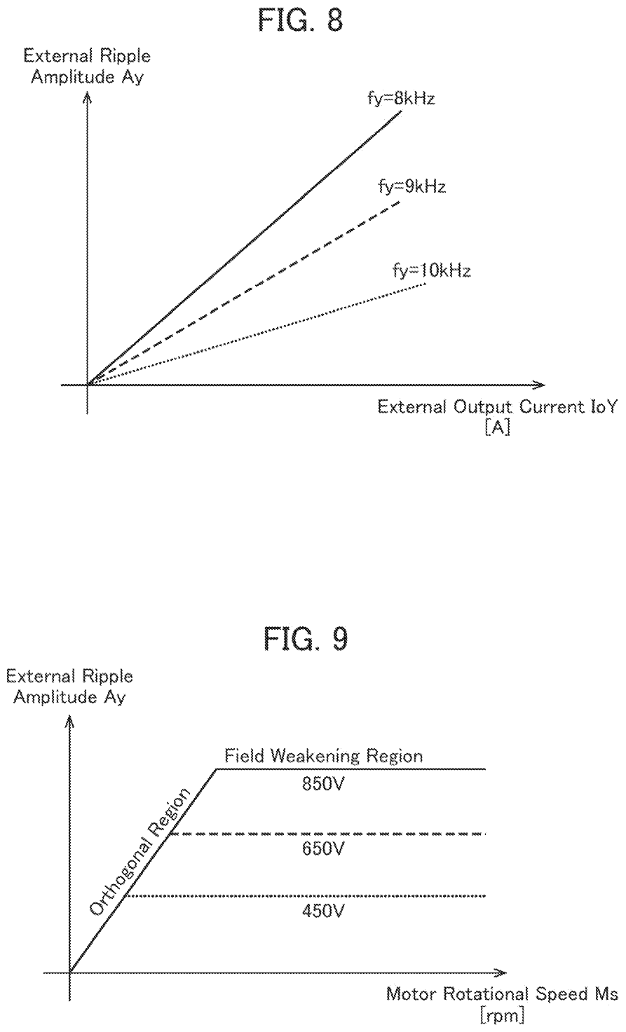

Specifically, also in the case of the external ripple RpY, similar to the case of the own ripple RpX, the larger the external ripple frequency fy is, the smaller the external ripple amplitude Ay is. As illustrated in FIG. 8, if the external ripple frequency fy is the same, the larger the external output current IoY from the boost converter 400 is, the larger the external ripple amplitude Ay is. The higher the output voltage Vo from the boost converter 400 is, the larger the external ripple amplitude Ay is. As illustrated in FIG. 9, until a field weakening region is reached, the higher the motor rotational speed Ms is, the larger the external ripple amplitude Ay is. According to them, the second table Ty is the four-dimensional table as described above. The second table Ty is preliminarily created based on an experiment and a simulation.

The second obtainer 40 illustrated in FIG. 1 obtains the external operating information iy. That is, the second obtainer 40 obtains the output voltage Vo, the external output current IoY, the external ripple frequency fy, and the motor rotational speed Ms. Specifically, the output voltage Vo can be obtained based on, for example, an actually measured value or a computed value of the voltage between terminals of the capacitor 480. The external output current IoY can be obtained by actual measurement by an ammeter or computation. The external ripple frequency fy can be obtained based on, for example, the frequency of duty control in the inverter 500, i.e., the frequency of carrier triangle waves. The motor rotational speed Ms can be obtained based on, for example, actual measurement by an encoder, a current feedback value or the like.

The second identifier 60 illustrated in FIG. 1 includes a temporary external ripple identifier 62, an external gain identifier 64, and an external ripple identifier 66. Hereinafter, the effective value of the external ripple RpY is called “external ripple effective value RpYe”, and a temporary value of the external ripple effective value RpYe is called “external ripple temporary effective value RpYt”. Note that “external ripple temporary effective value” may be read as “temporary value of external ripple”, and “external ripple effective value” may be read as “value of external ripple”. Hereinafter, the ratio of the external ripple effective value RpYe to the external ripple temporary effective value RpYt is called “external gain Gy”.

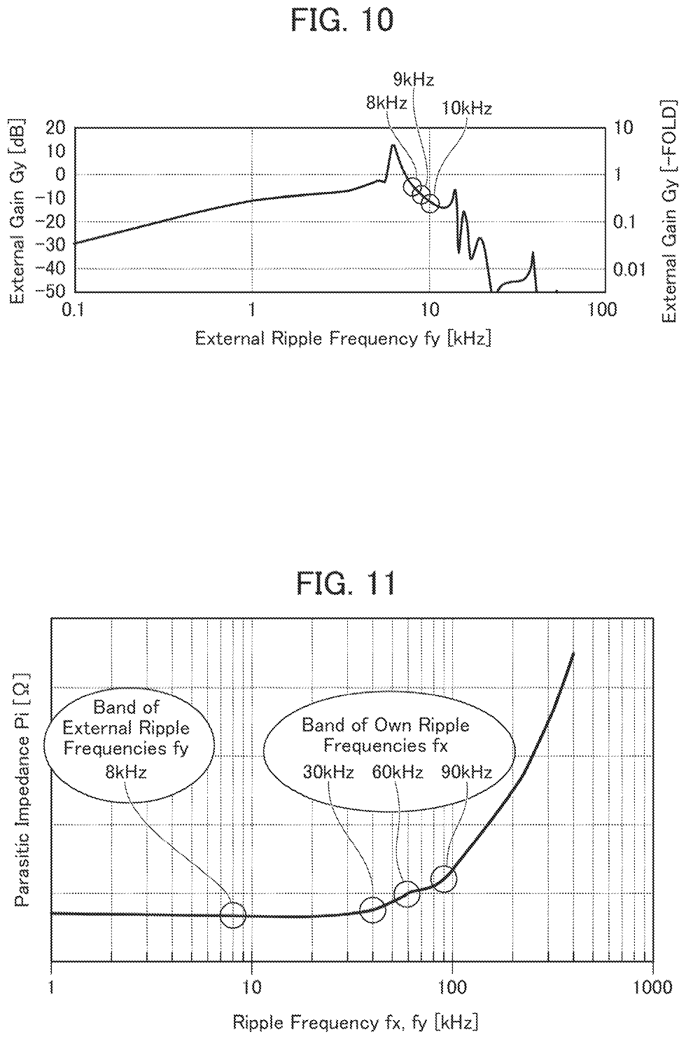

The description of the second identifier 60 is similar to the description of the aforementioned first identifier 50 when “first” is replaced with “second”, “own” is replaced with “external”, “FIG. 6” is replaced with “FIG. 10”, and symbols are replaced with corresponding ones. That is, as illustrated in FIG. 10, the external ripple frequency fy, and the external gain Gy have a predetermined relationship. Accordingly, the external ripple identifier 66 illustrated in FIG. 1 identifies the external ripple effective value RpYe flowing into the capacitor 480, based on the product of the identified external ripple temporary effective value RpYt and the external gain Gy.

Next, the loss calculator 70 and the temperature estimator 80 illustrated in FIG. 1 are described.

The loss calculator 70 calculates a power loss ΔP in the capacitor 480, based on the identified own ripple effective value RpXe, the identified external ripple effective value RpYe, and the parasitic impedance Pi that the capacitor 480 has.

Specifically, as illustrated in FIG. 11, the frequencies fx and fy of ripple, and the parasitic impedance Pi have a predetermined relationship. The loss calculator 70 stores information indicating the relationship. The loss calculator 70 illustrated in FIG. 1 then calculates the power loss ΔPx due to the own ripple RpX, based on the product (RpXe×RpXe×Pi) of the square of the identified own ripple effective value RpXe, and the parasitic impedance Pi at the obtained own ripple frequency fx. The loss calculator 70 calculates the power loss ΔPy due to the external ripple RpY, based on the product (RpYe×RpYe×Pi) of the square of the identified external ripple effective value RpYe, and the parasitic impedance Pi at the obtained external ripple frequency fy.

The loss calculator 70 calculates the power loss ΔP in the capacitor 480, based on the sum of the power loss ΔPx due to the own ripple RpX, and the power loss ΔPy due to the external ripple RpY.

The temperature estimator 80 estimates the capacitor temperature cT, based on the calculated power loss ΔP. Specifically, for example, the temperature estimator 80 calculates the heat generation rate in the capacitor 480, based on the power loss ΔP in the capacitor 480. The heat balance is calculated based on the time integral of the difference of the cooling rate subtracted from the heat generation rate. The change in temperature of the capacitor 480 is estimated by dividing the heat balance by the heat capacity of the capacitor 480, and the capacitor temperature cT is estimated.

Note that in a case in which the motor 600 and the capacitor 480 are cooled by cooling water in the same cooling system, the heat generated by the motor 600 sometimes affects the capacitor temperature cT. In this case, the temperature estimator 80 may have a table indicating the relationship between the heat generated by the motor 600, and the capacitor temperature cT. In this case, in consideration also of the heat generated by the motor 600, the capacitor temperature cT may be estimated.

According to this embodiment, the following advantageous effects can be achieved.

As illustrated in FIG. 1, the first identifier 50 identifies the own ripple effective value RpXe, based on the own-operating information ix and the first table Tx. The second identifier 60 identifies the external ripple effective value RpYe, based on the external operating information iy and the second table Ty. The loss calculator 70, and the temperature estimator 80 calculate the power loss ΔP, based on these own ripple effective value RpXe and external ripple effective value RpYe, and estimate the capacitor temperature CT. Accordingly, in consideration not only of the own ripple RpX but also of the external ripple RpY, the capacitor temperature cT can be estimated. Accordingly, the capacitor temperature cT can be accurately estimated.

As illustrated in FIG. 1, the loss calculator 70 calculates the power loss ΔP in the capacitor 480, based on the own ripple effective value RpXe identified by the first identifier 50, the external ripple effective value RpYe identified by the second identifier 60, and the parasitic impedance Pi that the capacitor 480 has. The temperature estimator 80 estimates the temperature of the capacitor 480, based on the calculated power loss ΔP. Thus, the capacitor temperature cT can be estimated by the simple scheme.

The first table Tx illustrated in FIG. 3 tabulates the relationship between the own-operating information ix, which includes the input current Ii, the own ripple frequency fx, and the boost ratio Bx, and the own ripple amplitude Ax. Accordingly, based on these parameters Ii, fx, and Bx, and the first table Tx, the own ripple amplitude Ax can be identified.

The second table Ty illustrated in FIG. 7 tabulates the relationship between the external operating information iy, which includes the output voltage Vo, the external output current IoY, the external ripple frequency fy, and the motor rotational speed Ms, and the external ripple amplitude Ay. Accordingly, based on these parameters Vo, IoY, fy, and Ms, and the second table Ty, the external ripple amplitude Ay can be identified.

As illustrated in FIG. 6, it is conceivable that the difference in own ripple frequency fx changes the impedance of wiring and the like, thus changing the own ripple RpX flowing into the capacitor 480 illustrated in FIG. 2. In regard to this point, the own gain identifier 53 illustrated in FIG. 1 identifies the own gain Gx, based on the own ripple frequency fx. The own ripple identifier 55 identifies the own ripple effective value RpXe, based on the identified own gain Gx. Accordingly, based on the own ripple frequency fx, the own gain Gx can be identified, and the own ripple effective value RpXe can be corrected.

As illustrated in FIG. 10, it is conceivable that the difference in external ripple frequency fy changes the impedance of wiring and the like, thus changing the external ripple RpY flowing into the capacitor 480 illustrated in FIG. 2. In regard to this point, the external gain identifier 64 illustrated in FIG. 1 identifies the external gain Gy, based on the external ripple frequency fy. The external ripple identifier 66 identifies the external ripple effective value RpYe, based on the identified external gain Gy. Accordingly, based on the external ripple frequency fy, the external gain Gy can be identified, and the external ripple effective value RpYe can be corrected.

In other words, the capacitor temperature estimation device 100 illustrated in FIG. 1 executes a capacitor temperature estimation method of estimating the capacitor temperature cT, based on each step of performing each operation described above. Also according to the capacitor temperature estimation method, advantageous effects similar to those in the case of the capacitor temperature estimation device 100 described above can be achieved.

### OTHER EMBODIMENTS

The embodiment described above may be changed, for example, as follows. In a case in which the relationship between one or more selected from the input current Ii, the own ripple frequency fx, and the boost ratio Bx illustrated in FIG. 3, and the own ripple amplitude Ax can be sufficiently computed based on an approximation formula, the one or more concerned may be omitted from the own-operating information ix in the first table Tx. Likewise, in a case in which the relationship between one or more selected from the output voltage Vo, the external output current IoY, the external ripple frequency fy, and the motor rotational speed Ms illustrated in FIG. 7, and the external ripple amplitude Ay can be sufficiently computed based on an approximation formula, the one or more concerned may be omitted from the external operating information iy in the second table Ty.

The first table Tx illustrated in FIG. 3 may be replaced with a table that indicates the relationship between the own-operating information ix, and the own ripple temporary effective value RpXt. Note that in this case, the own ripple temporary effective value RpXt corresponds to the own ripple information. Likewise, the second table Ty illustrated in FIG. 7 may be replaced with a table that indicates the relationship between the external operating information iy, and the external ripple temporary effective value RpYt. Note that in this case, the external ripple temporary effective value RpYt corresponds to the external ripple information.

In a case in which with respect to the relationship between the own ripple frequency fx and the own gain Gx as illustrated in FIG. 6, the value of the own gain Gx does not change much in the assumed range of the own ripple frequency fx, the own gain identifier 53 illustrated in FIG. 1 may be omitted. In this case, the own ripple temporary effective value RpXt described in the first embodiment may be adopted as it is as the own ripple effective value RpXe.

Likewise, in a case in which with respect to the relationship between the external ripple frequency fy and the external gain Gy as illustrated in FIG. 10, and the value of the external gain Gy does not change much in the assumed range of the external ripple frequency fy, the external gain identifier 64 illustrated in FIG. 1 may be omitted. In this case, the external ripple temporary effective value RpYt described in the first embodiment may be adopted as it is as the external ripple effective value RpYe.

The own-operating information ix illustrated in FIG. 1 may be four-dimensional information that further includes the own gain Gx, and the first table Tx may be a table that indicates the relationship between the four-dimensional own-operating information ix, and the own ripple effective value RpXe. In this case, the first identifier 50 may include neither the temporary own ripple identifier 51 nor the own gain identifier 53, and directly calculate the own ripple effective value RpXe, based on the obtained own-operating information ix and the first table Tx. Note that in this case, the own ripple effective value RpXe corresponds to the own ripple information.

Likewise, the external operating information iy may be five-dimensional information that further includes the external gain Gy, and the second table Ty may be a table that indicates the relationship between the five-dimensional external operating information iy, and the external ripple effective value RpYe. In this case, the second identifier 60 may include neither the temporary external ripple identifier 62 nor the external gain identifier 64, and directly calculate the external ripple effective value RpYe, based on the obtained external operating information iy and the second table Ty. Note that in this case, the external ripple effective value RpYe corresponds to the external ripple information.

Part of the function of the loss calculator 70 illustrated in FIG. 1 may be migrated to the first identifier 50, and the second identifier 60. Specifically, the first identifier 50 may perform operation to calculation of the power loss ΔPx due to the own ripple RpX, and the second identifier 60 may perform operation to calculation of the power loss ΔPy due to the external ripple RpY. In this case, the loss calculator 70 may then calculate the power loss ΔP in the capacitor 480, based simply on the sum of the power loss ΔPx due to the own ripple RpX, and the power loss ΔPy due to the external ripple RpY.

For example, an input terminal of external equipment, such as a DC motor, other than the inverter 500 may be connected to the output terminals 491 and 499 of the boost converter 400 illustrated in FIG. 2.

### EXPLANATION OF REFERENCE NUMERALS

10 First storage
20 Second storage
30 First obtainer
40 Second obtainer
50 First identifier
51 Temporary own ripple identifier
53 Own gain identifier
55 Own ripple identifier
60 Second identifier
62 Temporary external ripple identifier
64 External gain identifier
66 External ripple identifier
70 Loss calculator
80 Temperature estimator
100 Capacitor temperature estimation device
400 Boost converter
480 Capacitor
ix Own-operating information
Ii Input current (current input into boost converter)
fx Own ripple frequency
Bx Boost ratio
iy External operating information
Vo Output voltage (voltage output from boost converter to inverter)
IoY External output current (current output from boost converter to inverter)
fy External ripple frequency
Ms Motor rotational speed
Ax Own ripple amplitude (own ripple information)
Ay External ripple amplitude (external ripple information)
RpX Own ripple
RpXt Own ripple temporary effective value (temporary value of own ripple)
RpXe Own ripple effective value (value of own ripple)
RpY External ripple
RpYt External ripple temporary effective value (temporary value of external ripple)
RpYe External ripple effective value (value of external ripple)

What is claimed is:

1. A capacitor temperature estimation device for estimating a temperature of a capacitor in a boost converter, the capacitor temperature estimation device comprising:
a first storage configured to store a first table that tabulates a relationship between own-operating information as information about an operating state of the boost converter, and own ripple information as information about own ripple that is ripple current caused by operation of the boost converter;
a first obtainer configured to obtain the own-operating information;
a first identifier configured to identify the own ripple information, based on the own-operating information obtained and the first table;
a second storage configured to store a second table that tabulates a relationship between external operating information as information about an operating state of external equipment electrically connected to the boost converter, and external ripple information as information about external ripple that is ripple current caused by operation of the external equipment;
a second obtainer configured to obtain the external operating information;
a second identifier configured to identify the external ripple information, based on the external operating information obtained and the second table; and
a temperature estimator configured to estimate the temperature of the capacitor, based on the own ripple information identified and the external ripple information identified.

2. The capacitor temperature estimation device according to claim 1, further comprising:
a loss calculator configured to calculate a power loss in the capacitor, based on the own ripple information identified, the external ripple information identified, and a parasitic impedance that the capacitor has,
wherein the temperature estimator estimates the temperature of the capacitor, based on the power loss calculated.

3. The capacitor temperature estimation device according to claim 1,
wherein the external equipment is an inverter that converts power output from the boost converter, into AC power, and supplies the AC power to a motor, and
the external operating information includes at least one selected from a voltage output from the boost converter to the inverter, a current output from the boost converter to the inverter, a frequency of the external ripple, and a rotational speed of the motor.

4. The capacitor temperature estimation device according to claim 1,
wherein the own-operating information includes at least one selected from current input into the boost converter, a frequency of the own ripple, and a boost ratio of the boost converter.

5. The capacitor temperature estimation device according to claim 1,
wherein the second identifier includes:
a temporary external ripple identifier configured to identify a temporary value of the external ripple, based on the external operating information and the second table;
an external gain identifier configured to identify an external gain as a ratio of a value of the external ripple to the temporary value of the external ripple, based on a frequency of the external ripple; and
an external ripple identifier configured to identify the value of the external ripple that is to flow into the capacitor, based on the temporary value of the external ripple identified and the external gain identified, and
wherein the temperature estimator estimates the temperature of the capacitor, based on the value of the external ripple identified.

6. The capacitor temperature estimation device according to claim 1,
wherein the first identifier includes:
a temporary own ripple identifier configured to identify a temporary value of the own ripple, based on the own-operating information and the first table;
an own gain identifier configured to identify an own gain as a ratio of a value of the own ripple to the temporary value of the own ripple, based on a frequency of the own ripple; and
an own ripple identifier configured to identify the value of the own ripple that is to flow into the capacitor, based on the temporary value of the own ripple identified and the own gain identified, and
wherein the temperature estimator estimates the temperature of the capacitor, based on the value of the own ripple identified.

7. A capacitor temperature estimation method for estimating a temperature of a capacitor in a boost converter, the capacitor temperature estimation method comprising:
creating a first table that tabulates a relationship between own-operating information as information about an operating state of the boost converter, and own ripple information as information about own ripple that is ripple current caused by operation of the boost converter;
obtaining the own-operating information;
identifying the own ripple information, based on the own-operating information obtained and the first table;
creating a second table that tabulates a relationship between external operating information as information about an operating state of external equipment electrically connected to the boost converter, and external ripple information as information about external ripple that is ripple current caused by operation of the external equipment;
obtaining the external operating information;
identifying the external ripple information, based on the external operating information obtained and the second table; and
estimating the temperature of the capacitor, based on the own ripple information identified and the external ripple information identified.
